(19) United States
(12) Patent Application Publication
(10) Pub. No.: US 2008/0108245 A1
(43) Pub. Date: May 8, 2008

(54) Protection mechanism for terminal of memory stick adapter

(76) Inventors: SHU-CHIN CHU, Pingzhen City (TW); CHING CHUNG HUNG, Pingzhen City (TW)

Correspondence Address: HDSL, 4331 STEVENS BATTLE LANE, FAIRFAX, VA, 22033, US

(21) Appl. No.: 11/930,353

(22) Filed: Oct. 31, 2007

(30) Foreign Application Priority Data
Nov. 2, 2006 (TW) 095219334

(51) Int. Cl. H01R 13/64; H01R 33/00; H05K 7/14

(52) U.S. Cl. 439/374; 361/807

(57) ABSTRACT

A protection mechanism for terminals of memory stick adapter includes two outer casings, a circuit board unit, and a framework. Multiple plugging terminals disposed to one end of the circuit board unit for connecting to the memory stick are covered up or exposed by means of a mobile protection cover. A locating groove is disposed on a sliding plate each provided on both sides of the cover An elastic arm on an inner edge of each of both sides of the framework is disposed with an inclined protruding block to secure the cover in conjunction with the locating groove. The block breaking away from the locating groove as the elastic arm moves out upon insertion of the memory stick to retreat the cover and expose those plugging terminals for facilitating insertion of the memory stick.

### BACKGROUND OF THE INVENTION

1. Field of the Invention

The present invention is related to a protection mechanism for terminals of a memory stick adapter, and more particularly, to a mobile mechanism that allows terminals to be properly covered up under protection and to be automatically exposed as driven by the memory stick for the memory stick to achieve connection.

2. Description of the Prior Art

Many consumer electronic products take advantage of compact memory sticks for data storage since a memory stick is removable and provides easy portability. For example, a digital camera comprehensively applies memory stick to store video data. To make it easy for a computer to read out, a memory stick is usually provided with an adapter which is disposed with multiple plugging terminals to plug in the computer for executing data transmission. Whereas those terminals are very small and fragile, they are vulnerable to be curved or broken when 15 subject to abnormal compression by external force thus to fail plugging of the memory stick. It appears that when not protected, the adapter has a limited service life and high damage rate. Therefore, how to design a mechanism to protect plugging terminals without compromising easy and smooth use is indeed one of the most important topic inviting R&D efforts.

### SUMMARY OF THE INVENTION

The present invention is to provide a protection mechanism for terminals in a memory sick adapter by having a mobile protection cover to serve as the protection mechanism. When not used, the mobile protection cover automatically covers up in position at where plugging terminals are located to conceal, and thus protects them. Upon plugging the memory stick to the adapter, the protection mechanism automatically releases it from its located position and retreats to expose those plugging terminals for them to connect to the memory stick.

To achieve the purpose, the adapter contains two outer casing, a circuit board unit and a framework. The circuit board unit has its one end disposed with multiple plugging terminals for connection to the memory stick. Those plugging terminals are protected by or exposed out of a mobile protection cover. To allow the mobile protection cover to be located in position to protect those plugging terminals before connecting to the memory stick, each of both sides of the mobile protection cover is provided with a sliding plate and a locating groove, and a corresponding elastic arm is disposed on an inner edge of each of both sides of the framework. An inclined protruding block is provided on a flat surface of the elastic arm and is capable of being adapted to locating groove. Under normal condition, the inclined protruding block of the elastic arm automatically falls into and interlocked with the locating groove so as to locate the mobile protection cover for the mobile protection cover to effectively protect those plugging terminals. A containing portion is disposed on an inner edge of the elastic arm. The containing portion when compressed by insertion of the memory stick forces the elastic arm to move out. Meanwhile a slope of the inclined protruding block touches an edge of the locating groove for the elastic arm to obliquely more in opposite direction against the locating groove. Accordingly, the inclined protruding block will clear off the locating groove to release its interlocking status with the locating groove, and the mobile protection cover is pushed inwardly by the memory stick to expose those plugging terminals for completing its connection to the memory stick.

### BRIEF DESCRIPTION OF THE DRAWINGS

FIG. 1 is a perspective view of the present invention.

FIG. 2 is an exploded view of the present invention.

FIG. 3 is a perspective view of a mobile protection cover in the present invention.

FIG. 4 is a schematic view showing a mechanism of the mobile protection cover in the present invention is held in position.

FIG. 5 is a bird's view showing the mobile protection cover in the present invention is held in position.

FIG. 6 is a bird's view showing an appearance of a memory stick to be adapted to the present invention.

FIG. 7 is a bird's view showing that an elastic arm is forced to move out when contained by the memory stick in the present invention.

FIG. 8 is a bird's view showing that the mobile protection cover in the present invention is released from its located position.

FIG. 9 is a bird's view showing that the memory stick is inserted to the present invention.

### DETAILED DESCRIPTION OF THE PREFERRED EMBODIMENTS

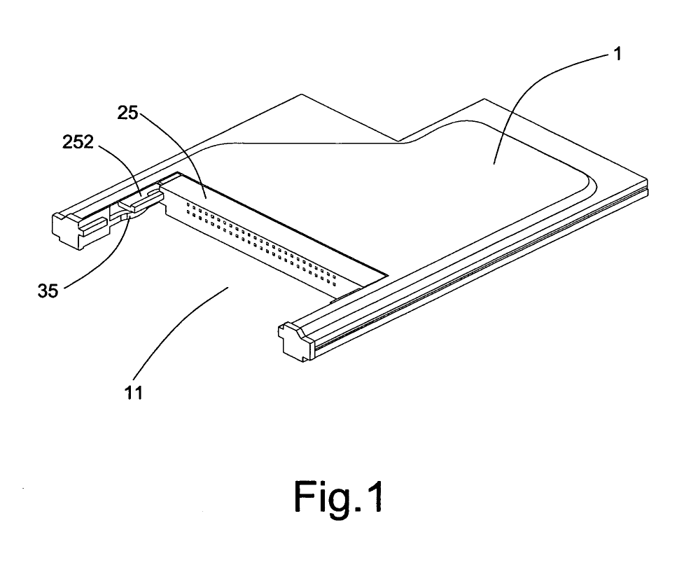

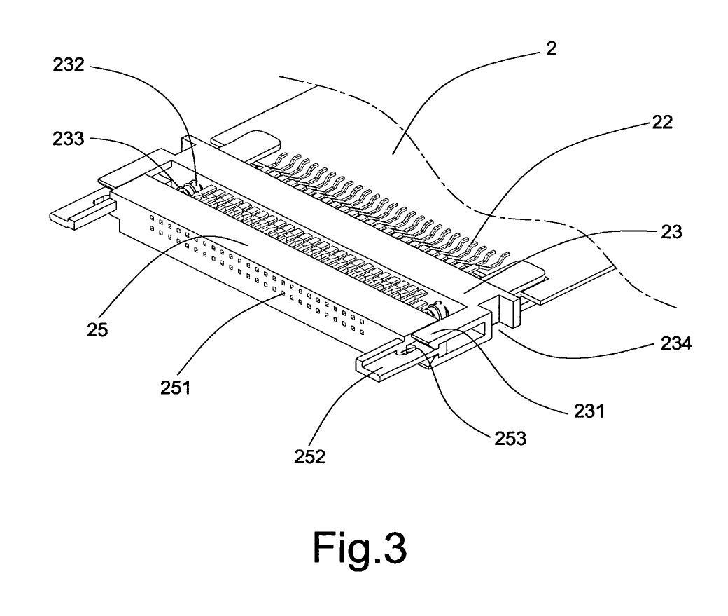

Referring to FIGS. 1, 2, and 3, a protection mechanism for terminals in a memory stick adapter is comprised of two outer casings 1, a circuit board unit 2, and a framework 3.

Both two outer casings 1 are abutted to each other to define an internal space, and a memory stick socket 11 is provided at where appropriately. The circuit board unit 2 has one end related to a port 21 which may be of but not limited to a port complying with Express Card standard interface specification, and an additional USB port may be disposed at where appropriately as desired, and on another end in relation to the port 21 of the circuit board unit 2 is fixed with multiple plugging terminals 22 with each penetrating through a locating base 23 to extend for a given length form the locating base 23. One feed bar 231 roughly in C-shape is disposed on each of both sides of the locating base 23, and a corresponding locking groove 234 is provided on each of both sides of the locating base 23. A mobile protection cover 25 is disposed to an outer edge of the locating base 23 and multiple through holes 251 are provided on the mobile protection cover 25 at where corresponding to each and all plugging terminals 22 are located. The mobile protection cover 25 is allowed to slide in and out against those plugging terminals via those through holes 251; and a sliding plate 252 is disposed on each of both sides of the mobile protection cover 25. Each sliding plate 252 roughly in T-shape has one end placed laterally in the feed bar 231 so to allow the sliding plate 252 to slide in and out between both feed bars 231 without escaping from both feed bars 231. Two locating posts 232 are disposed at where appropriately between the locating base 23 and the protection cover 25 with each locating post 232 inserted with a coil 233; and the coil 233 is capable of providing a force to push out the mobile protection cover 25 under normal conditions; and a locating groove 253 is disposed at where appropriately to each sliding plate 252.

The framework 3 is comprised of a side frame 31, another side frame 32, a connection frame 33, and a connection bar 34 to accommodate the circuit board unit 2. Two locking blocks 311, 321 are respectively disposed on an internal side of the side frame 31 and another side frame 32 to be respectively interlocked with two locking grooves 234 from the circuit board unit 2. Two elastic arms 35 are respectively provided on an inner edge each of the side frame 31 and another side frame 32. A containing portion 351 is disposed at where appropriately on an inner edge of the elastic arm 35, and the containing portion 351 roughly indicates an arc. An inclined protruding block 352 is disposed on a flat surface of the elastic arm 35 at where immediate to the locating groove 253. A slope 353 inclining from inside out is formed on a top of the inclined protruding block 352. Two guide rails 39 are respectively provided on opposite inner edges of the side frame 31 and another side frame 32.

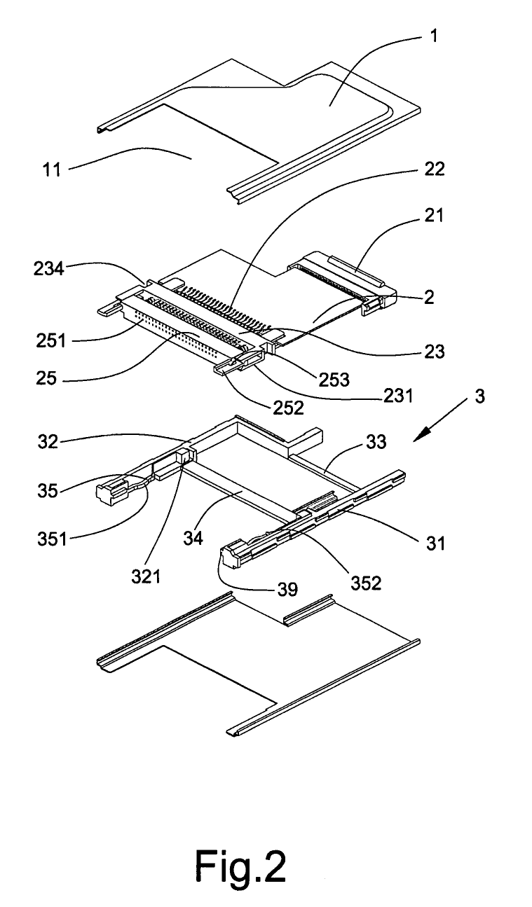

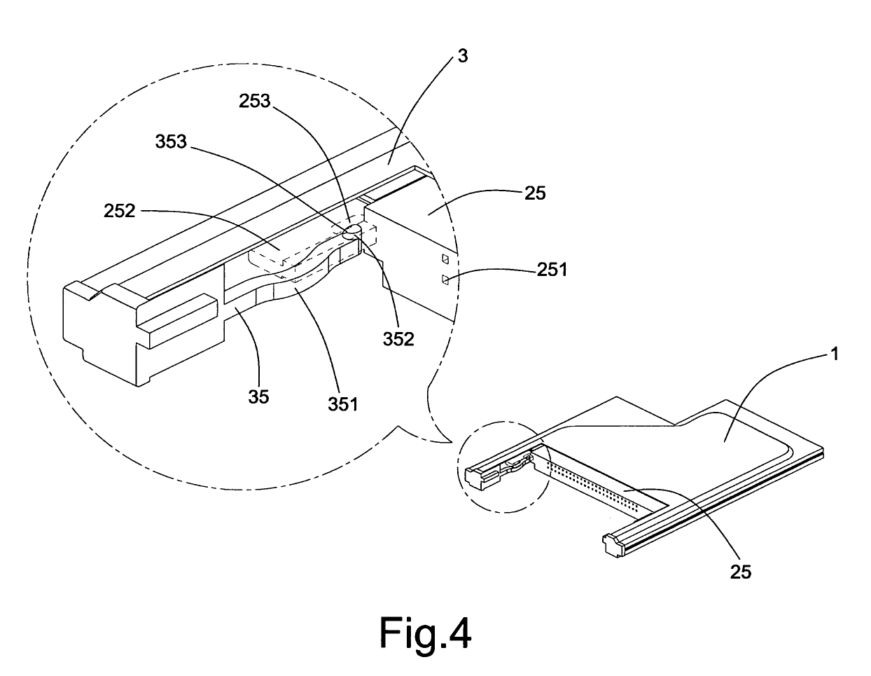

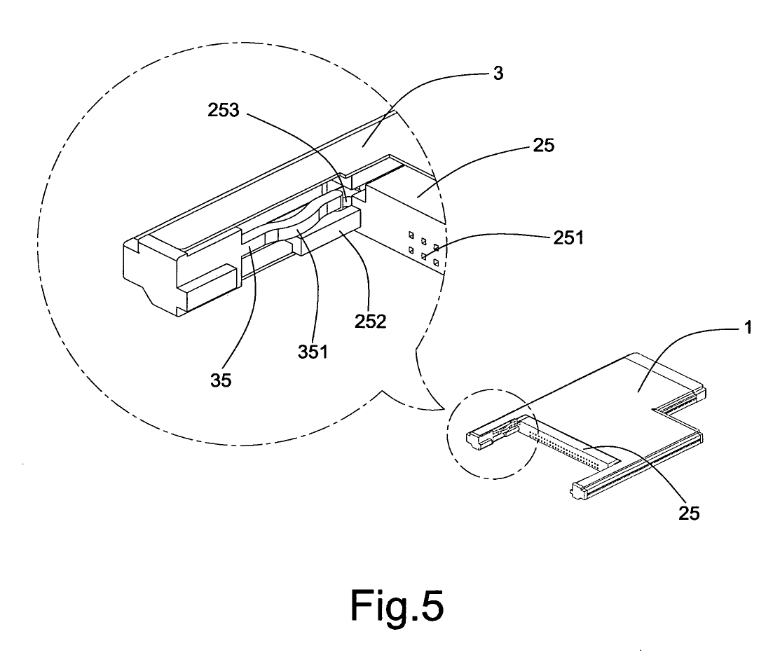

Now referring to FIGS. 2, 4, and 5 showing that the present invention is not yet inserted by a memory stick 9, the inclined protruding block 352 of each elastic arm 35 is merely trapped in the locating groove 253 since the mobile protection cover 25 is normally pushed out by the coil 233 and the sliding plate 252 is located at the farthest edge in relation to the feed bar 231. Accordingly, both of the inclined protruding block 352 and the locating groove 253 are interlocked to each other and the mobile protection cover 25 will not be easily retreated even when squeezed by external force. Therefore, those plugging terminals 22 are concealed inside and effectively protected by the mobile protection cover 25.

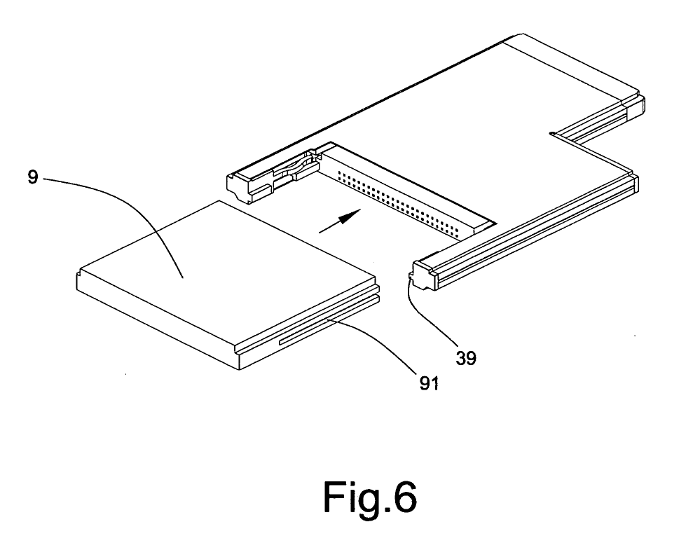

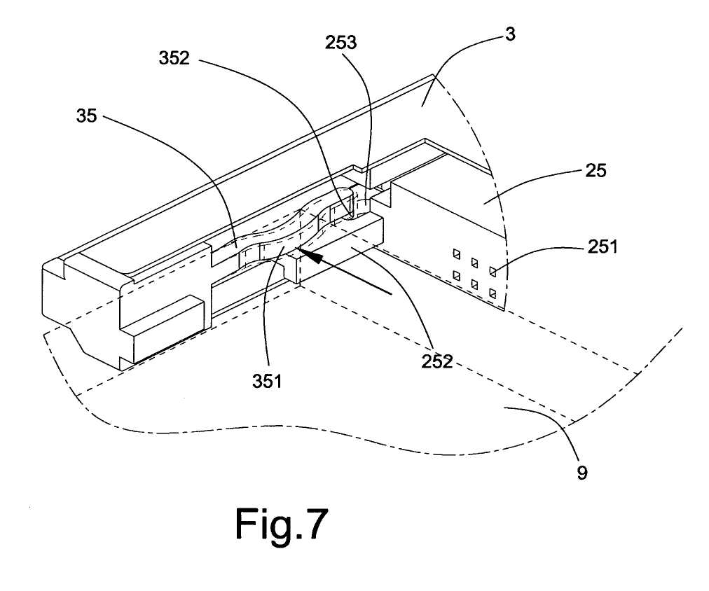

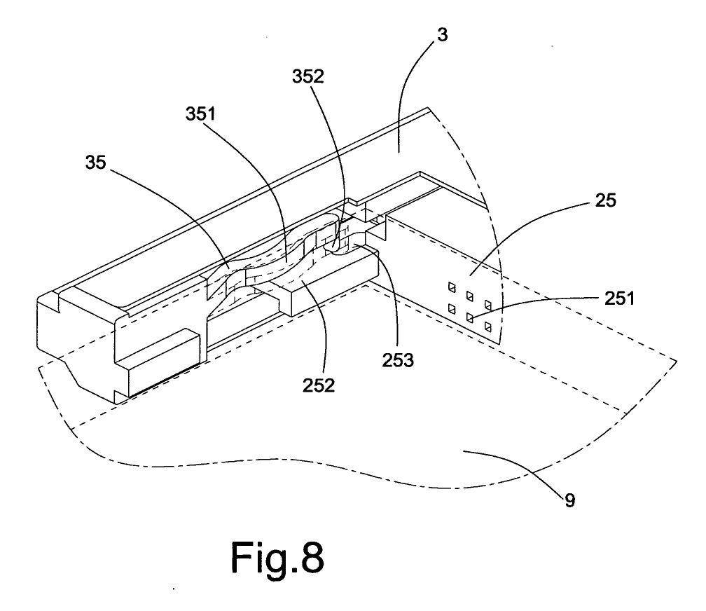

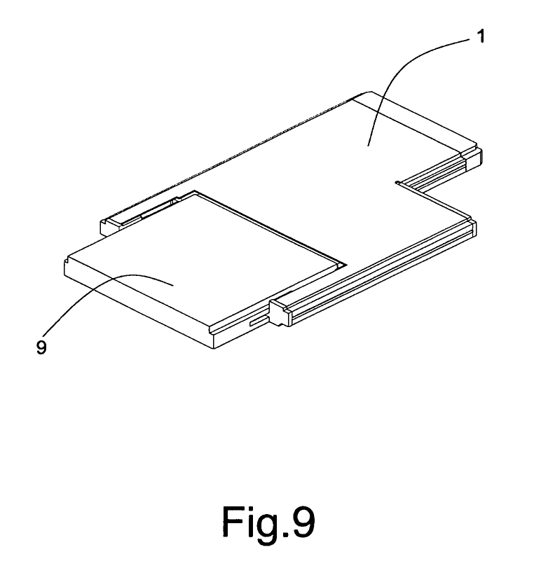

Upon receiving insertion by the memory stick 9 as illustrated in FIG. 6, both slides 91 of the memory stick 9 are inserted into the protection mechanism by aligning at both guide rails 39. Both sides of the memory stick 9 contacts the containing portions 351, and both elastic arms 35 are externally ejected by the memory stick 9 as illustrated in FIG. 7. Whereas the inclined protruding block 352 of each elastic arm 35 is provided with the slope 353, the inclined protracting block 352 clears out of the locating groove 253 to move out by having the slope 353 to contact the edge of the locating groove 253 as illustrated in FIG. 8. The inclined protruding block 352 is released from the locating groove 253 and the mobile protection 25 compresses the coil 233 and heads for the locating base 23 to expose those plugging terminals 22 out of their respectively through holes to connect to the memory stick 9 since the mobile protection cover 25 is pushing its way into the memory stick socket 11 as illustrated in FIG. 9. If the memory stick 9 is withdrawn from the memory stick socket 11, the coil 233 will push out the mobile protection cover 25 for each inclined protruding block 352 to fall back into and interlock with the locating groove 253 for automatically providing the protection.

1. A protection mechanism for terminals of memory stick adapter, comprising:
two outer casings closing upon on each other to define an internal space, and a memory stick socket being disposed at where appropriately;
a circuit board unit with one end related to a port and multiple plugging terminals being disposed on the end of the circuit board in relation to the port, each plugging terminal penetrating through a locating base and exposed out of the locating base for a predetermined length, and a feed bard being disposed on each of both sides of the locking base, a mobile protection cover being disposed on an outer edge of the locating base, multiple through holes being disposed to the mobile protection cover at where corresponding to each of all those plugging terminals being located, a sliding plate roughly indicating a T shape with one end mounted in the feed bar being disposed on both sides of the mobile protection cover; a locating post inserted with a coil being disposed at where appropriately between the locating base and the mobile protection cover; and a locating groove being disposed at where appropriately on the sliding plate; and
a framework including two side frames a connection frame, and a connection bar to accommodate the circuit board unit; two elastic arms being respectively provided on both side frames; a containing portion being disposed at where appropriately on an inner edge of the elastic arm, and an inclined protruding block being disposed on a flat surface of the elastic arm at where immediate to the locating groove to fall in or break away from the locating groove depending on the operating status.

2. The protection mechanism for terminals of memory stick adapter as claimed in claim 1, wherein the port is related to a connection structure complying with Express Card Standard Interface Specification.

3. The protection mechanism for terminals of memory stick adapter as claimed in claim 1, wherein an additional USB port is disposed at where appropriately on the circuit board unit as desired.

4. The protection mechanism for terminals of memory stick adapter as claimed in claim 1, wherein both sides of the locating base are respectively disposed with a locking groove, a locking block is disposed on an inner side of each of both side frames, and the locking block is capable of adapting to the locking groove.

5. The protection mechanism for terminals of memory stick adapter as claimed in claim 1, wherein the containing portion is made roughly indicating an arc.

6. The protection mechanism for terminals of memory stick adapter as claimed in claim 1, wherein a slope inclining from inside out is formed on a top of the inclined protruding block.

7. The protection mechanism for terminals of memory stick adapter as claimed in claim 1, wherein a guide rail is disposed to an inner side edge of each side frame.
